(19) United States
(12) Patent Application Publication
(10) Pub. No.: US 2009/0100313 A1
(43) Pub. Date: Apr. 16, 2009

(54) METHODS AND APPARATUSES OF MATHEMATICAL PROCESSING

(75) Inventors: Warren J. GROSS, Montreal (CA); Shie MANNOR, Montreal (CA); Saeed SHARIFI TEHRANI, Montreal (CA)

Correspondence Address: FREEDMAN & ASSOCIATES, 117 CENTREPOINTE DRIVE, SUITE 350, NEPEAN, ONTARIO, K2G 5X3, CA

(73) Assignee: The Royal Institution for the Advancement of Learning/McGill University, Montreal (CA)

(21) Appl. No.: 12/250,830

(22) Filed: Oct. 14, 2008

Related U.S. Application Data
(60) Provisional application No. 60/960,728, filed on Oct. 11, 2007.

(51) Int. Cl. H03M 13/05; G06F 7/38; G06F 7/58; G06F 11/10

(52) U.S. Cl. 714/752; 708/233; 708/250; 714/E11.032

(57) ABSTRACT

Disclosed is a pipelined iterative process and system. Data is received at an input port and is processed in a symbolwise fashion. Processing of each symbol is performed other than relying on completing the processing of an immediately preceding symbol such that operation of the system or process is independent of an order of the input symbols.

### FIELD OF THE INVENTION

The invention relates generally to data communications and more particularly to stochastic processes.

### SUMMARY OF THE INVENTION

In accordance with embodiments of the invention there is provided a system comprising: logic circuitry comprising a plurality A of logic components; and, a plurality B of randomization engines, each of the plurality B of randomization engines being connected to a predetermined portion of the plurality A of logic components, each of the plurality B of randomization engines for providing one of random and pseudo-random numbers to each logic component of the respective predetermined portion of the plurality A of logic components, wherein each of the plurality B of randomization engines comprises at least a random number generator.

In accordance with embodiments of the invention there is provided a method comprising: receiving digital data for iterative processing; iteratively processing the data based on a first precision; changing the precision of the iterative process to a second precision; iteratively processing the data based on the second precision; and, providing processed data after a stopping criterion of the iterative process has been satisfied.

In accordance with embodiments of the invention there is provided a system comprising: a logic circuit comprising a plurality of logic components, the logic components being connected for executing an iterative process such that operation of the logic components is independent from a sequence of input bits; and, a pipeline having a predetermined depth interposed in at least a critical path connecting two of the logic components.

In accordance with embodiments of the invention there is provided a system comprising: a plurality of saturating up/down counters, each of the plurality of saturating up/down counters for receiving data indicative of a reliability and for determining a hard decision in dependence thereupon, wherein each of the saturating up/down counters stops one of decrementing and incrementing when one of a minimum and a maximum threshold is reached.

In accordance with embodiments of the invention there is provided a method comprising: providing a plurality of up/down counters; providing to each of the plurality of up/down counters data indicative of a reliability, wherein the data indicative of a reliability have been generated by components of a logic circuitry with the components being in a state other than a hold state; at each of the plurality of up/down counters determining a hard decision in dependence upon the received data; and, each of the plurality of up/down counters providing data indicative of the respective hard decision.

In accordance with embodiments of the invention there is provided a method comprising: providing a plurality of up/down counters; providing to each of the plurality of up/down counters data indicative of a reliability; at each of the plurality of up/down counters determining a hard decision in dependence upon the received data, wherein updating of the up/down counters is started after a number of decoding cycles determined in dependence upon the convergence behavior of the decoding process; and, each of the plurality of up/down counters providing data indicative of the respective hard decision.

In accordance with embodiments of the invention there is provided a method comprising: providing a plurality of up/down counters; providing to each of the plurality of up/down counters data indicative of a reliability; at each of the plurality of up/down counters determining data representing a reliability decision in dependence upon the received data; and, each of the plurality of up/down counters providing the data representing a reliability.

In accordance with embodiments of the invention there is provided a method comprising: providing a plurality of up/down counters; providing to each of the plurality of up/down counters data indicative of a reliability; at each of the plurality of up/down counters determining a hard decision in dependence upon the received data, wherein a step size for decrementing and incrementing the up/down counters is changed in dependence upon at least one of convergence behavior of the decoding process and bit error rate performance of the decoding process; and, each of the plurality of up/down counters providing data indicative of the respective hard decision.

In accordance with embodiments of the invention there is provided a system comprising: a logic circuit comprising a plurality A of logic components, the logic components being connected for executing a stochastic process; a plurality B of memories connected to a portion of the plurality A of logic components for providing an outgoing bit when a respective logic component is in a hold state, wherein the plurality B comprises a plurality C of subsets and wherein the memories of each subset are integrated in a memory block.

### BRIEF DESCRIPTION OF THE DRAWINGS

Exemplary embodiments of the invention will now be described in conjunction with the following drawings, in which:

FIG. 1 is a simplified block diagram of a randomization system according to the invention;

FIG. 2 is a simplified flow diagram of a method for changing precision according to the invention;

FIG. 3a is a simplified flow diagram of a prior art method for implementing an arithmetic function;

FIG. 3b is a simplified flow diagram of a prior art pipeline for implementing an arithmetic function;

FIG. 3c is a simplified flow diagram of a prior art pipeline for implementing an iterative arithmetic function;

FIG. 3d is a simplified block diagram of a pipelining connection according to the invention; and,

FIG. 4 is a simplified block diagram of an EM memory block according to the invention.

### DETAILED DESCRIPTION OF EMBODIMENTS OF THE INVENTION

The following description is presented to enable a person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the scope of the invention. Thus, the present invention is not intended to be limited to the embodiments disclosed, but is to be accorded the widest scope consistent with the principles and features disclosed herein.

In stochastic decoders Random Number Generators (RNGs) are employed to generate one of random numbers and pseudo-random numbers. RNGs are implemented using, for example, Linear Feedback Shift Registers (LFSRs). In stochastic decoders RNGs are used to generate random or pseudo-random numbers for:

a) converting probabilities into stochastic streams using comparators; and/or,
b) providing random addresses in Edge Memories (EMs) and Internal Memories (IMs).

To generate random numbers for the various components of a stochastic decoder such as comparators, EMs, and IMs, it is possible to use one group of different LFSRs and XOR their bits in each Decoding Cycle (DC). However, this technique is inefficient for the hardware implementation of stochastic decoders, in particular for stochastic decoders comprising a large number of nodes. Generating the random numbers using one group of RNGs and transmitting the same to the various components requires long connecting transmission lines within the decoder, limiting the clock frequency of the decoder—i.e. slowing the decoder—and increasing power consumption.

An alternative technique of generating different random numbers for each component—comparators, EMs, and IMs—of the stochastic decoder requires a large number of LFSRs and connecting transmission lines.

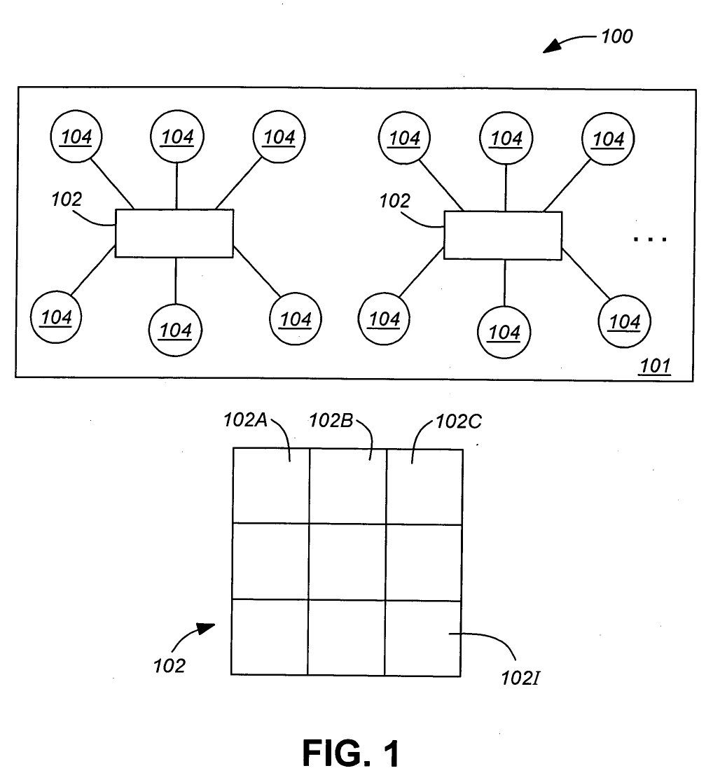

Referring to FIG. 1a randomization system 100 is shown. Here, the random or pseudo-random numbers are provided by a plurality of Randomization Engines (REs) 102. Each RE 102 provides random or pseudo-random numbers to a predetermined portion of components 104 of a stochastic decoder 101. Each RE 102 comprises a group of RNGs—such as LFSRs—102A to 102I. The number of REs and their placement as well as the number of RNGs within each RE 102 are determined in dependence upon the application. Of course, it is possible to provide different REs with a different number of RNGs for use in a same system. For example, for a length 1024 stochastic decoder instead of using one large RE, it is possible to use 16 smaller—and usually independent—REs 102 in which each RE 102 generates random or pseudo-random numbers for EMs and comparators used in 1024/16=64 variable nodes.

To further reduce the complexity of the REs 102 and the system 100, it is also possible to use same random or pseudo-random numbers for EMs and comparators connected to different variable nodes, respectively. For example, the EMs and comparators connected to variable nodes i and j share the same numbers.

It is further possible to use same random or pseudo-random numbers for EMs and comparators connected to a same variable node. For example, if a 64-bit EM associated with a variable node requires a 6 bit random or pseudo-random address number and a comparator associated with the variable node requires a 9 bit random or pseudo-random number, it is possible to generate a 9 bit random or pseudo-random number of which 6 bits are used by the EM and all 9 bits are used by the comparator.

Using the randomizing system 100 supports substantially reduced routing in the stochastic decoder, thus providing for higher clock frequency while decoding performance loss is negligible.

As is evident, the randomization system 100 is not limited to stochastic decoders but is also beneficial in numerous other applications where, for example, a logic circuitry comprises numerous components requiring random or pseudo-random numbers.

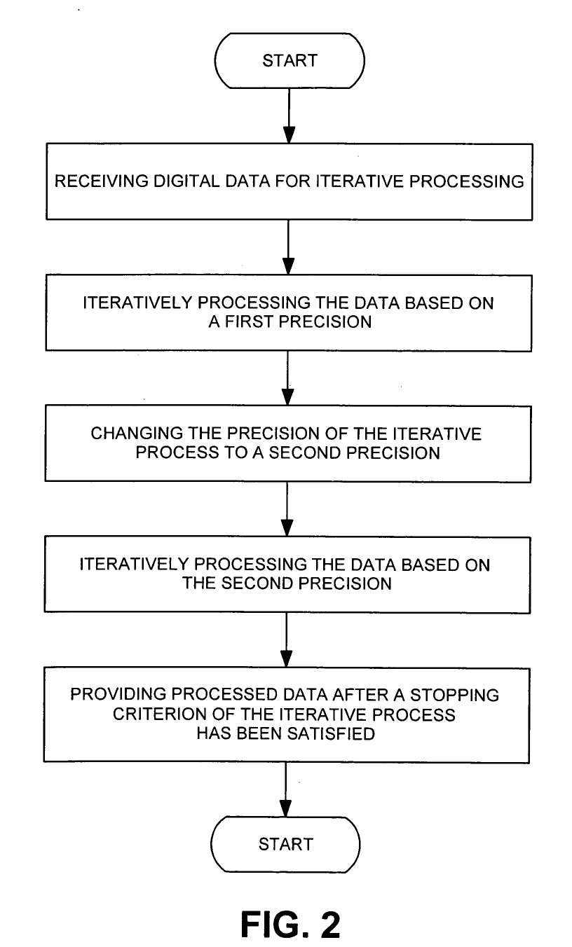

Referring to FIG. 2, a simplified flow diagram of a method for changing precision is shown. Upon receipt, digital data are iteratively processed based on a first precision. While executing the iterative process the precision is changed to a second precision and the iterative process is then continued based on the second precision until a stopping criterion is satisfied. The method is beneficial in stochastic computation, stochastic decoding, iterative decoding, as well as in numerous other applications based on iterative processes.

The method is based on changing the precision of computational nodes during the iterative process. It is possible to implement the method in order to reduce power consumption, achieve faster convergence of iterative processes, better switching activity, lower latency, better performance—for example, better Bit-Error-Rate (BER) performance of stochastic decoders—or any combination thereof. The term better as used hereinabove refers to more desirable as would be understandable to one of skill in the art.

Depending on the application, the process is started using high precision and then changed to lower precision or vice versa. Of course, it is also possible to change the precision numerous times during the process—for example, switching between various levels of lower and higher precision—depending on, for example, convergence or switching activity.

In an example, stochastic decoders use EMs to provide good BER performance. One way to implement EMs is to use M-bit shift registers with a single selectable bit—via EM address lines. According to an embodiment of the invention, the stochastic decoding process is started with 64 bit EMs and after some DCs the precision of the EMs is changed to 32 bit, 16 bit etc. . . . The precision of the EMs is changed, for example, by modifying their address lines, i.e. at the beginning the generated 6 bit address lines for an EM ranges from 0 to 2⁶−1=63, then changed to a range from 0 to 2⁵−1=31 (the 6^{th} bit becoming 0) and so on. Of course, this method is also applicable for Internal Memories (IMs).

The embodiment is also implementable using counter based EMs and IMs. For example, it is possible to increase or decrease the increment and/or decrement step size of up/down counters during operation.

The DCs where the precision is changed are determined, for example, in dependence upon the performance or convergence behavior—for example, mean and standard deviation—of the process. For example, if the average number of DCs for decoding with 64 bit is K DCs with the standard deviation of S DCs, the precision is changed after K+S DCs.

In addition to changing the precision of components such as EMs, it is also possible to dynamically change the precision of messages between computational nodes. For example, in a bit serial decoding process, after a predetermined number of iterations, the messages sent from computational node i to node j are changed every 2 iterations instead of every one iteration, i.e. a same output bit is sent for 2 iterations from computational node i to node j.

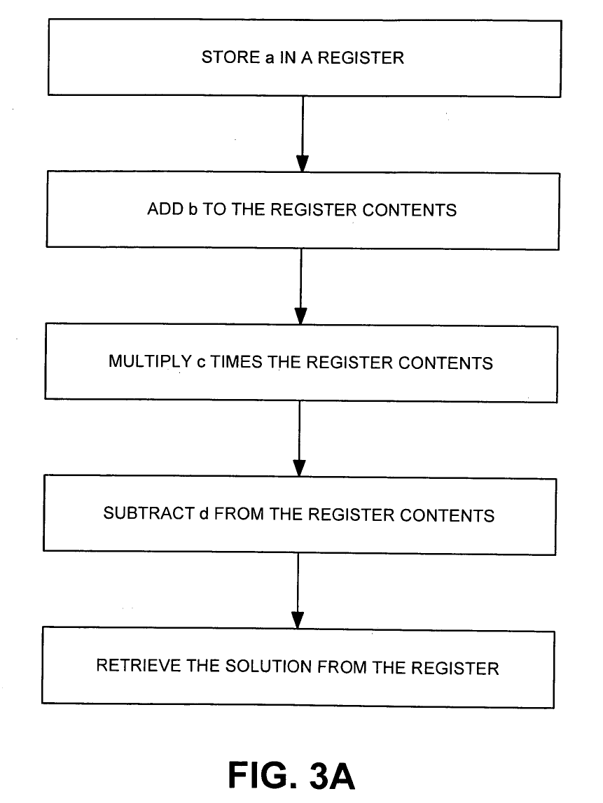

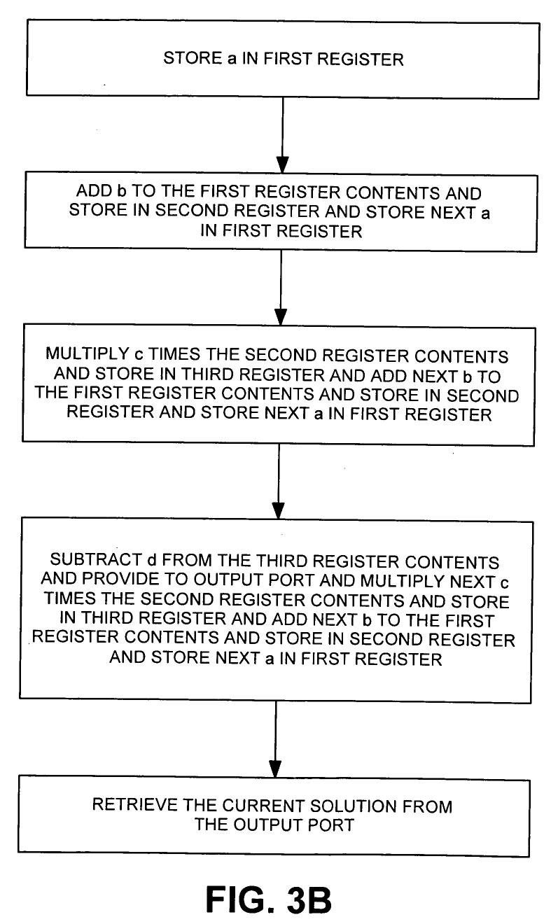

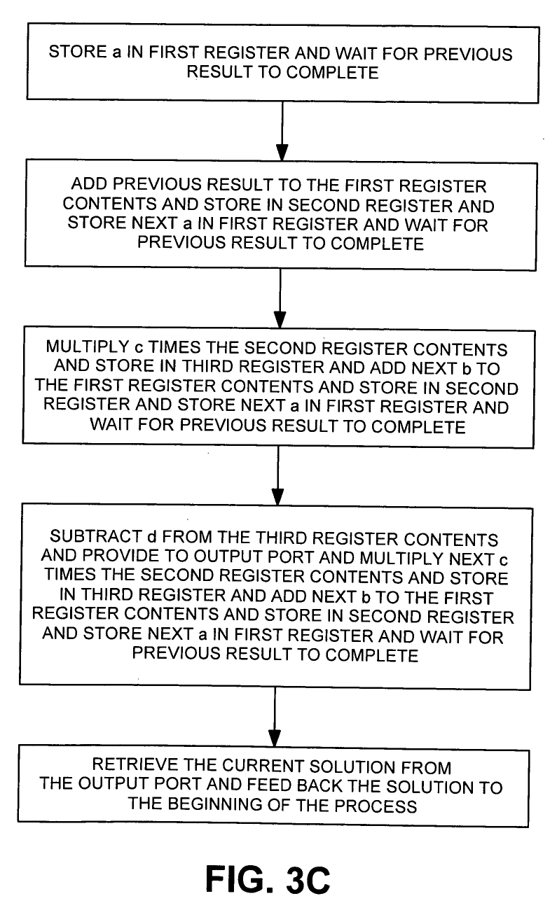

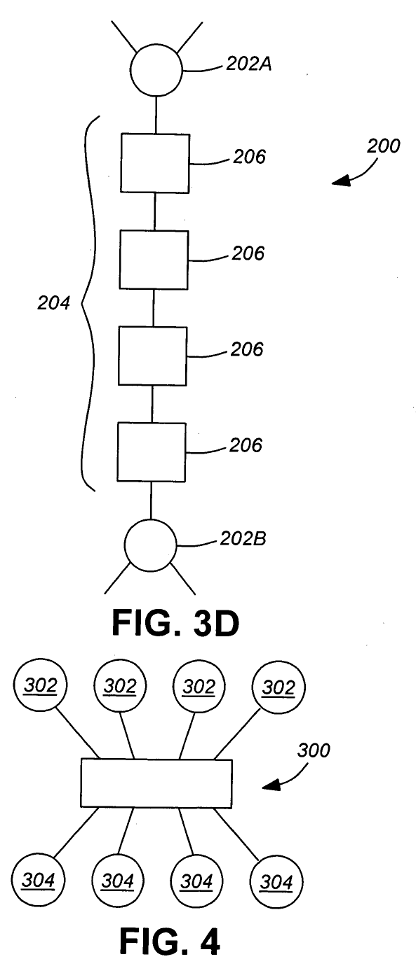

Pipelining is a commonly used approach to improve system performance by performing different operations in parallel, the different operations relating to a same process but for different data. For example, to implement (a+b)×c−d, a simple arithmetic process, several designs work. When implemented for one time execution as shown in FIG. 3a, the result is an addition, a multiplication, and a subtraction requiring 3 operations (excluding set up). If this process is to be repeated sequentially numerous times for different data, it is straightforward to move data from one arithmetic operator to another in a series—a pipeline—of three thereby operations allowing loading of new data into the adder—the first operation block—each clock cycle as shown in FIG. 3b. This results in a system having the same latency—time from beginning an operation to time when the operation is completed—but supporting a much higher bandwidth—here a process result is provided at an output port of the pipeline every operation cycle. Of course, if 50 operations were used the pipeline would be longer, but the value of providing results at the output port every clock cycle remains. Thus for data processing of streaming data wherein each input value is processed similarly, pipelining is an excellent architecture for enhancing data throughput.

Though for simplicity, FIGS. 3a and 3b show a simple arithmetic process without parallelism, a pipeline is also operable in parallel, either supporting parallelism therein or in parallel with other processes that do not affect the overall data throughput. In a logic circuit, the Critical Path (CP) is defined as a path with the largest delay in the circuit. Typically, the data path with the largest delay forms the Critical Path.

For highly parallel architectures, the CP typically is determinative of a maximum speed the logic circuit is able to achieve. For example, if the delay of the CP is 4 ms the maximum speed—clock frequency—the logic circuit is able to achieve is I/0.004=250 operations per second. Pipelining is useful for allowing more operations to be “ongoing” and thereby increasing a number of operations per second to increase the speed and/or the throughput of a logic circuit. For example, using depth 4 pipeline—a pipeline having four concurrent processes each at a different stage therein—the delay of the CP in the previous example is unchanged but the maximum achievable speed is increased to 1000 operations per second. Referring to FIG. 3c, shown is a simple pipeline for executing an iterative process for (a+“previous result”)*c−d. As will be noted, because the first step requires an output value from a previous iteration, there is no savings by pipelining of the process. This is typical for iterative processes since the processes usually rely on data results of previous iterations.

Unfortunately, in circuits which implement iterative processes such as iterative decoders, use of pipelining is not considered beneficial since in such applications pipelining is a limiting factor for the throughput. For executing iterative processes computational elements communicate with each other—for example, a feedback—and their output data at time N depend on their previous input data and/or output data at time N−1. For example, suppose that the output data of node A is used by node B and the output data of node B is used by node A—for example, in the next iteration—and also suppose that this scheme is repeated for 32 iterations. Here, a depth 4 pipeline between the nodes A and B increases the time input data are received by each computational node by a factor of 4 and hence, instead of 32 iterations, 32*4=128 iterations are now needed in the pipelined circuit, i.e. throughput is reduced.

Referring to FIG. 3d, a simplified block diagram of a pipelining connection 200 is shown. Here, a pipelined CP 204 is used to connect two (2) nodes 202A and 202B of a logic circuit for implementing an iterative stochastic process. For example, a depth 4 pipeline is used comprising 4 registers 206. Fortunately, for implementing stochastic processes such as, for example, stochastic computing or stochastic decoding, the computational nodes operate on a stream of stochastic bits and do not depend on the sequence of input bits, i.e. the output data at time N do not depend on the input data determined at time N−1. Therefore, it is possible to interpose an arbitrary number of registers into the CP to increase the throughput and/or to break the CP to a predetermined level. Further, it is possible to use different depths of pipelining for different parts of the logic circuit. For example, a depth 4 pipeline is used for a first CP and a depth 3 pipeline is used for a second other CP of the logic circuit.

For example, in LDPC decoders variable nodes send output data to parity check nodes and parity check nodes send their output data to the variable nodes, which is repeated for a predetermined number of iterations or until all parity checks are satisfied. The CP of a LDPC decoder is usually determined by interconnections between variable nodes and parity check nodes, i.e. interleaver. Therefore, when depth K pipelining is used to break the CP, the pipelined decoder needs K times more iterations to provide same decoding performance. In a stochastic LDPC decoder, stochastic variable and parity check nodes do not depend on the sequence of stochastic bits received. Therefore, it is possible to place any number of registers between the variable nodes and the parity check nodes to break the CP and/or increase the throughput to a predetermined level.

It is noted that the pipelining connection is also beneficial for the hardware implementation of various other iterative processes in which the computational nodes do not depend on a sequence of input data or input bits, for example bit-flipping decoding methods. In a decoder employing bit-flipping the parity check nodes inform the variable nodes to increase or decrease the reliability—i.e. to flip the decoded bits at the variable node. Therefore, the variable nodes do not depend on the order of such messages and hence it is possible to implement the pipelining connection as described herein.

In stochastic decoders such as, for example, stochastic LDPC decoders and stochastic Turbo decoders up/down counters are used to gather output data of, for example, variable nodes and to provide a “hard-decision.” The up/down counters are fed with the output data of the respective variable nodes. Therefore, when the output data of the variable node is 1 the corresponding up/down counter is incremented and when the output data is 0 the up/down counter is decremented. The sign bit of the counter at each DC determines if the output data is positive or negative and hence it determines the “hard decision” on the value of the counter—for example, sign-bit=0 means a 0 decoded bit and sign-bit=1 means a 1 decoded bit.

It is noted, that in some applications the up/down counter is not updated at the beginning of the decoding process. For example, if the decoding process comprises 1000 DCs, the counters are updated after DC=200.

In a circuit for processing data representing reliabilities saturating up/down counters are used to gather the output data of, for example, variable nodes and to provide a “hard-decision,” where the counter stops decrementing or incrementing when it reaches a minimum or maximum threshold, respectively.

In a first embodiment for processing data representing reliabilities the up/down counters are fed with output data that are generated in a state other than a hold state in order to provide a better BER performance and/or faster convergence.

In a second embodiment for processing data representing reliabilities updating of the up/down counters is started after a number of DCs determined in dependence upon the convergence behavior of the decoding process—for example, the mean and the standard-deviation of convergence—and/or the BER performance of the decoder.

In a third embodiment for processing data representing reliabilities the output values of the up/down counters are used as soft-information representing output reliabilities. These output reliabilities are used for adaptive decoding processes such as, for example, adaptive Reed Solomon decoding and BCH decoding and/or are provided as input data to another decoding stage such as, for example, a Turbo code stage.

In a forth embodiment for processing data representing reliabilities the step size for decrementing and incrementing the up/down counters is changed in dependence upon at least one of convergence behaviour and BER performance of the decoding process in order to improve the decoding performance and/or convergence.

It is noted, that it is possible to employ the above circuit and methods in bit-flipping decoding and similar bit serial processes.

Implementation of EMs substantially increases the complexity of stochastic decoders. Referring to FIG. 4, a simplified block diagram of an EM memory block 300 is shown. Here, EMs for being placed on each of the edges between a plurality of nodes 302 and respective nodes 304 are integrated into the EM memory block 300. For example, if a stochastic decoder comprises 1024 EMs with a length of M=64 bits, the EMs are integrated into 32 EM memory blocks 300 in which each block has M×(1024/32) bits. In this case, each EM memory block 300 has a 32 bit read port and a 32 bit write port. Of course, it is also possible to employ EM memory blocks 300 of different size in a same stochastic decoder. Using the EM memory blocks 300 allows for substantially reduced complexity of stochastic decoders and is beneficial for Application-Specific Integrated Circuit (ASIC) implementation of stochastic decoders.

Considering that K EMs, each with length of Mbits, are grouped into a M×K memory block, the operation of this block is as follows:

1) In each DC, at least one read operation and one write operation is performed on the memory block. The data port length for read and write operations is K bit, i.e. K bits are written and K bits are read in each DC.
2) The address for the read operation is generated in a random or pseudo-random fashion—in the range of [0, M−1]. The address for the write operation is generated using, for example, a counter in a round-robin fashion to provide a First-In-First-Out (FIFO) operation for the K EMs, i.e. the write operation is performed on the oldest bit in each EM. Optionally, both, the read address and the write address is the same for the memory block, i.e. all K EMs.

Assuming that in a DC XEMs of the K EMs are in a hold state and K−X EMs are in a state other than a hold state:

3) Read Operation: The outcome of the read operation is K bits. X bits of the K bits belong to EMs/nodes in the hold state and hence are used as the outgoing bits for the nodes which are in the hold state. K−X bits are not used as the outgoing bits. Instead the new regenerative bits produced by the K−X nodes that are in a state other than the hold state are used as the outgoing bits for these nodes.
4) Write Operation: K bits are written to the block. Of the K EMs, K−X EMs are in a state other than the hold state and X EMs are in the hold state. K−X bits of the K bits written to the memory block are new regenerative bits—generated by the K−X nodes that are in a state other than the hold state. There are various possibilities for implementing the write operation for the N EMs that are in the hold state:
a) Using an outcome of the read operation for the write operation, i.e. the same X bits are used for the write operation.
b) Performing an extra read operation on the address designated for the write operation and then using the same X bits for the write operation.
c) Buffering some—for example, most—recent regenerative bits for each EM and when the EM is in the hold state selecting a bit from the buffer for the write operation of the respective EM, for example, in one of a random and pseudo-random fashion.

Of course, the memory blocks are also applicable for implementing IMs, for example, inside high degree equality nodes. It is further possible to integrate different EMs or IMs into a same memory block. Optionally, the randomization system 100 is employed to provide more than one RE for an entire circuit, for example one RE for a group of closely spaced REs. Alternatively, the randomization system 100 is employed to provide one RE for each memory block, i.e. the random address for each memory block is generated by an independent RE.

Numerous other embodiments of the invention will be apparent to persons skilled in the art without departing from the spirit and scope of the invention as defined in the appended claims.

What is claimed is:

1. A system comprising:
a logic circuit comprising a plurality of logic components, the logic components connected for executing an iterative process such that operation of the logic components is independent from a sequence of input symbols; and,
a pipeline having a predetermined depth interposed in at least a critical path connecting two of the logic components.

2. A system as defined in claim 1 wherein the pipeline comprises a predetermined number of registers in dependence upon the predetermined depth.

3. A system according to claim 1 wherein the pipeline forms part of circuit for implementing a stochastic process.

4. A system according to claim 3 wherein the stochastic process comprises a stochastic decoding process.

5. A system according to claim 4 wherein the stochastic process is for implementing a stochastic LDPC process.

6. A system according to claim 1 wherein the pipeline forms part of circuit for implementing a bit flip process.

7. A system according to claim 6 wherein the bit flip process comprises a bit flip decoding process.

8. A system according to claim 1 wherein a symbol consists of a bit.

9. A method comprising:
providing a sequence of input symbols to a first circuit; and,
processing the input symbols iteratively using a pipeline such that operation of the first circuit is independent from the sequence of input symbols.

10. A method according to claim 9 wherein each symbol consists of a bit.

11. A system comprising:
logic circuitry comprising a plurality A of logic components; and,
a plurality B of randomization engines, each of the plurality B of randomization engines being connected to a predetermined portion of the plurality A of logic components, each of the plurality B of randomization engines for providing one of random and pseudo-random numbers to each logic component of the respective predetermined portion of the plurality A of logic components, wherein each of the plurality B of randomization engines comprises at least a random number generator.

12. A system as defined in claim 11 wherein a same random number generator is connected to a plurality of logic components.

13. A system as defined in claim 12 wherein a same random number generator is connected for providing a first random number of N bits to a first of the plurality of logic components and a second random number of M bits to a second other of the plurality of logic components, where N does not equal M.

14. A system as defined in claim 11 comprising edge memories, wherein each edge memory comprises a different random number generator.

15. A system as defined in claim 11 comprising a plurality of edge memories, wherein each edge memories of the plurality of edge memories disposed in close proximity one to another comprise a same random number generator and wherein edge memories of the plurality of edge memories disposed other than in close proximity one to another comprise different random number generators.

16. A system as defined in claim 11 comprising internal memories, wherein each internal memory comprises a different random number generator.

17. A system as defined in claim 11 comprising a plurality of internal memories, wherein each internal memories of the plurality of internal memories disposed in close proximity one to another comprise a same random number generator and wherein internal memories of the plurality of internal memories disposed other than in close proximity one to another comprise different random number generators.

18. A system as defined in claim 11 wherein the system comprises a decoder circuit.

19. A system as defined in claim 18 wherein the decoder circuit comprises a plurality of randomization engines, each of the plurality of randomization engines being connected to a predetermined portion of the decoder circuit.
